(19) United States
(12) Patent Application Publication
(10) Pub. No.: US 2018/0212056 A1
(43) Pub. Date: Jul. 26, 2018

(54) STRAINED SEMICONDUCTOR-ON-INSULATOR BY DEFORMATION OF BURIED INSULATOR INDUCED BY BURIED STRESSOR

(71) Applicant: Acorn Technologies, Inc., La Jolla, CA (US)

(72) Inventors: Paul A. Clifton, Redwood City, CA (US); Andreas Goebel, Mountain View, CA (US)

(21) Appl. No.: 15/877,273

(22) Filed: Jan. 22, 2018

Related U.S. Application Data
(60) Provisional application No. 62/449,172, filed on Jan. 23, 2017.

(51) Int. Cl. H01L 29/78; H01L 29/786; H01L 29/66; H01L 27/092; H01L 21/762; H01L 21/8238

(52) U.S. Cl. CPC H01L 29/7846; H01L 29/7849; H01L 29/78654; H01L 21/823807; H01L 27/092; H01L 21/76275; H01L 21/76283; H01L 29/66772

(57) ABSTRACT

Etching trench isolation structures into a semiconductor structure that includes an upper thin semiconductor layer disposed over a buried insulator layer and a buried compressively strained stressor layer under the buried insulator layer, the compressively strained stressor layer being disposed on an underlying semiconductor substrate, causes edge relaxation of the compressively strained stressor layer. The edge relaxation results in the buried insulation layer being deformed, thus inducing tensile strain in an upper surface of the thin semiconductor layer across at least a first portion of a lateral extent of the thin semiconductor layer between walls of one or more trenches formed by the etching.

### RELATED APPLICATIONS

This is a NONPROVISIONAL of, claims priority to, and incorporates by reference U.S. Provisional Application No. 62/449,172, filed Jan. 23, 2017.

### FIELD OF THE INVENTION

The present invention relates to semiconductor devices and, in particular, to such devices as include a strained semiconductor layer in which the strain results, at least in part, from deformation of a buried insulator layer due to edge relaxation of a buried stressor layer.

### BACKGROUND

Straining of an active semiconductor channel layer is an important consideration in the manufacture of high performance field effect transistors on fully depleted semiconductor-on-insulator wafers. In particular, tensile strain in a silicon n-channel metal oxide semiconductor field effect transistor (MOSFET), applied in the direction of current flow from source to drain, can increase the current compared to unstrained silicon, all other factors being equal. A strained semiconductor layer on insulator is also of value in some other integrated circuit applications where the performance of a device is improved by the presence of tensile strain in the active semiconductor layer. Such devices include optoelectronic (photonic) devices including light emitters and detectors.

As described in the Applicant's U.S. Pat. No. 8,395,213 and U.S. Pat. No. 9,406,798, each incorporated herein by reference, strain is induced in a thin surface semiconductor layer overlying a buried insulator by partial elastic edge relaxation of a buried stressor layer underlying the buried insulator. Partial elastic edge relaxation of a buried stressor layer is caused (achieved) by etching trenches through the buried stressor layer. The free surface presented by the sidewall of an etched trench allows the in-plane stress in the buried stressor to be relieved locally and the buried stressor material is able to move laterally to some extent to relieve some of the stress within it. The in-plane tensile strain induced in the thin surface semiconductor layer is of opposite sign to the in-plane strain in the buried stressor layer. If the buried stressor layer has in-plane compressive stress then elastic edge relaxation of the buried stressor consequentially causes overlying layers of material to be tensile strained in the plane of the layers. The in-plane tensile strain induced in the layers above extends generally a distance of tens of nanometers to a few hundreds of nanometers from the trench sidewall. If trench sidewalls are formed with a separation of less than approximately 500 nm, the relaxation of the buried stressor and consequential straining of the thin semiconductor layer above may extend laterally sufficiently for some degree of strain to be induced across the whole width of the thin semiconductor layer extending between the trenches.

### SUMMARY OF THE INVENTION

In an embodiment of the present invention, a semiconductor-based device structure includes a substrate (e.g., including silicon), wherein first and second walls of one or more trench isolation structures extend partially into the substrate and a substrate interface region extends between the first and second walls. A buried stressor structure, e.g., a silicon germanium layer, is disposed on the substrate interface region and extends over a lateral extent between the first and second walls, the buried stressor structure has in-plane compressive stress. A buried insulation layer, e.g., including silicon dioxide, is disposed over the buried stressor structure, and a thin upper semiconductor layer, e.g., silicon, silicon germanium, germanium, germanium tin, or another alloy of germanium, a group IV semiconductor, a semiconducting alloy, a compound of group IV elements, a II-VI compound semiconductor, or a III-V compound semiconductor such as GaN, InGaN, and AlGaN, etc., is disposed over the buried insulation layer. The thin upper semiconductor layer extends between the first and second walls and in-plane tensile strain is induced within a first portion of the thin upper semiconductor layer extending between the first and second walls, the strain being induced, at least in part, by deformation of the buried insulation layer. An integrated circuit device may have an active region at least partially in the first portion of the thin upper semiconductor layer. Such an integrated circuit device may also include a gate dielectric layer on the surface semiconductor layer separating the surface semiconductor layer from a gate electrode so that the surface of the thin semiconductor layer extending between the first and second walls provides at least a part of a channel region of a MOS transistor. Notably, the buried insulation layer is deformed, with the deformation being caused by edge relaxation of the buried stressor structure.

In various embodiments of the invention, the buried insulation layer may be silicon dioxide with a thickness between 5 nm and 80 nm. In some instances, the buried stressor structure may include compressively strained silicon germanium alloy grown epitaxially on the substrate. Alternatively, the buried stressor substrate may include compressively strained silicon nitride. In some embodiments, the thin upper semiconductor layer has a thickness between 0.2 nm and 50 nm.

In some embodiments of the invention, the lateral extent between the first and second walls is less than 500 nm. Partial relaxation within the buried insulation structure may be non-uniform over that lateral extent.

In some embodiments, the thin semiconductor layer is silicon and the surface of the thin semiconductor layer has in-plane tensile strain along two perpendicular directions.

In still further embodiments of the invention, a semiconductor device manufacturing process includes: providing an SOI substrate having an upper thin semiconductor layer (e.g., a group IV semiconductor, a semiconducting alloy, a compound of group IV elements, a II-VI compound semiconductor, or a III-V compound semiconductor) over a buried insulator layer (e.g., silicon dioxide) and a buried, compressively-strained stressor layer under the buried insulator layer, etching through the upper thin semiconductor layer, the buried insulator, and the buried compressively-strained stressor layer and into the underlying wafer in a pattern defined by a mask layer, thereby at least partially relaxing the buried compressively-strained stressor layer and causing deformation of the buried insulator layer. The deformation of the buried insulator layer induces tensile strain in the upper surface of the thin semiconductor layer across at least a first portion of a lateral extent of the thin semiconductor layer between walls of one or more trenches formed by the etching. An active region an integrated circuit device may be formed in the first portion of the surface semiconductor layer. For example, an n-channel MOSFET device formed in accordance with embodiments of the invention may include a channel region in the tensile strained surface of the thin semiconductor layer.

In some embodiments of the invention, the tensile strain induced in the upper surface of the thin semiconductor layer is uniaxial tensile strain. In other embodiments of the invention, the tensile strain induced in the upper surface of the thin semiconductor layer is biaxial tensile strain.

In accordance with embodiments of the invention, the deformation of the buried insulator layer is a result of inducing tensile strain in the buried insulator layer. The buried stressor layer may be an in-plane compressively stressed silicon nitride layer, which, in some instances, has a compressive stress of greater than 200 MPa prior to etching through the stressed buried insulator structure. Alternatively, the buried stressor layer may include in-plane compressively strained silicon germanium.

In accordance with some embodiments of the invention, the buried insulator layer may be coupled to the buried stressor layer through a wafer bonding process. Further, the lateral extent of the surface semiconductor layer may be 250 nm or smaller. In some cases, the tensile strain within the top surface of thin semiconductor layer is non-uniform over the lateral extent of the thin semiconductor layer.

### BRIEF DESCRIPTION OF THE DRAWINGS

The present invention is illustrated by way of example, and not limitation, in the figures of the accompanying drawings, in which:

FIG. 1(a) is a transmission electron micrograph showing, in part, an interface between a silicon oxide buried insulator layer and a silicon germanium buried stressor layer in a semiconductor device structure formed, in accordance with embodiments of the present invention, by wafer bonding.

FIG. 1(b) illustrates an annotated version of the transmission electron micrograph in FIG. 1(a).

FIG. 2 shows schematically an SOI wafer according to an aspect of the present invention.

FIG. 3 shows schematically the wafer of FIG. 2 after further processing.

FIG. 4 illustrates the wafer of FIG. 3 after further processing.

FIG. 5 illustrates the wafer of FIG. 4 after further processing.

FIGS. 6, 7, and 8 illustrate portions of a CMOS device according to preferred embodiments of the present invention.

### DETAILED DESCRIPTION

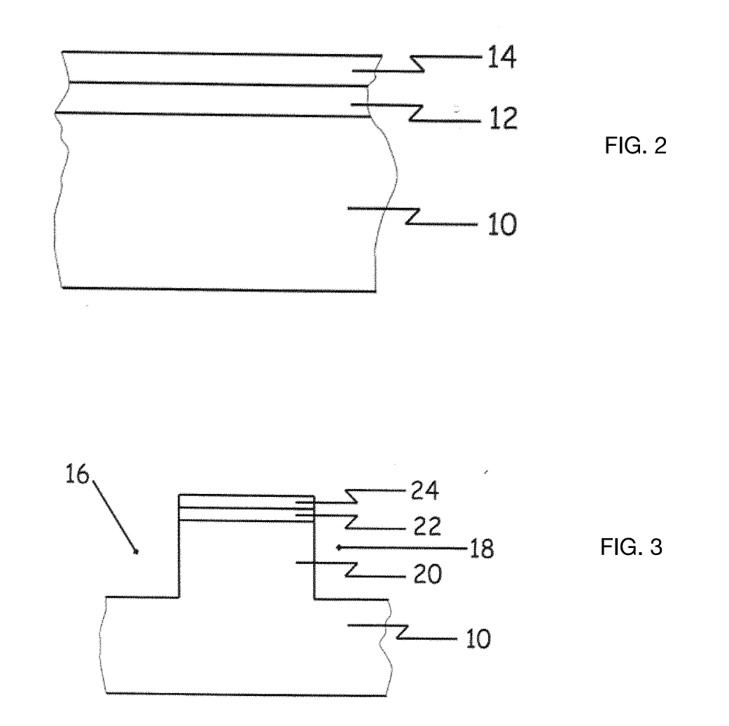

FIGS. 2-8 are adapted from Applicant's above-cited U.S. Pat. No. 9,406,798. FIG. 3 illustrates in schematic cross section a substrate 10 having a buried insulator structure 12 and a surface semiconductor layer 14 formed by any of the strategies discussed in U.S. Pat. No. 9,406,798. The materials of substrate 10, buried insulator structure 12 and surface semiconductor layer 14 may be selected broadly in accordance with aspects of the present invention but will be described here in terms of an embodiment having a silicon substrate 10, a buried insulator structure 12 including a stressed silicon germanium or silicon nitride layer and at least one oxide buffering layer, and a surface silicon layer 14. Substrates and surface layers other than silicon, such as germanium, etc., may be used.

Following formation of an SOI wafer as illustrated in FIG. 2, a manufacturing process continues by etching trenches 16, 18 through the layers 14 and 12 and into the substrate 10 to a sufficient depth and with the trenches sufficiently closely spaced to allow edge relaxation to induce strain over a major portion of surface semiconductor layer 14. The end result of this process is illustrated in FIG. 3. The illustrated trenches 16, 18 can be formed using processing typically used for trench isolation structures and, preferably, are formed to extend through the stressed buried insulator structure and partially into the underlying silicon substrate 10. The trenches may be different portions of a continuous network of trenches.

The sidewalls of the trenches define a surface region 20 of the substrate, a stressed buried insulator structure 22 on the substrate surface region 20, and a strained surface silicon layer 24 on the stressed buried insulator structure 22. Each of the region 20, layer 22 and layer 24 extend laterally between the sidewalls of trenches 16 and 18. Etching the trenches allows the stressed buried insulator structure 22 to relax and deform, as described below, and hence to induce tensile stress within the silicon layer 24 above the etched BOX structure 22.

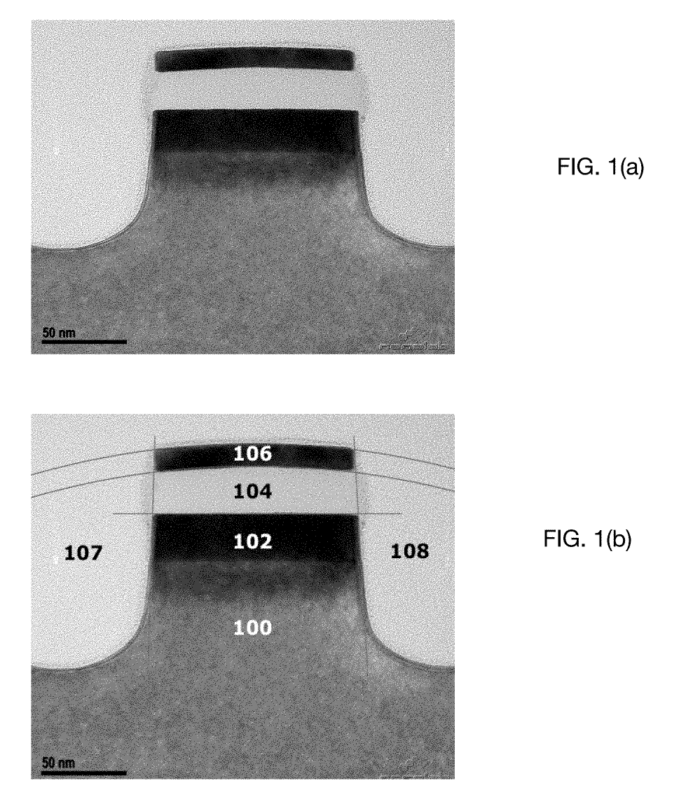

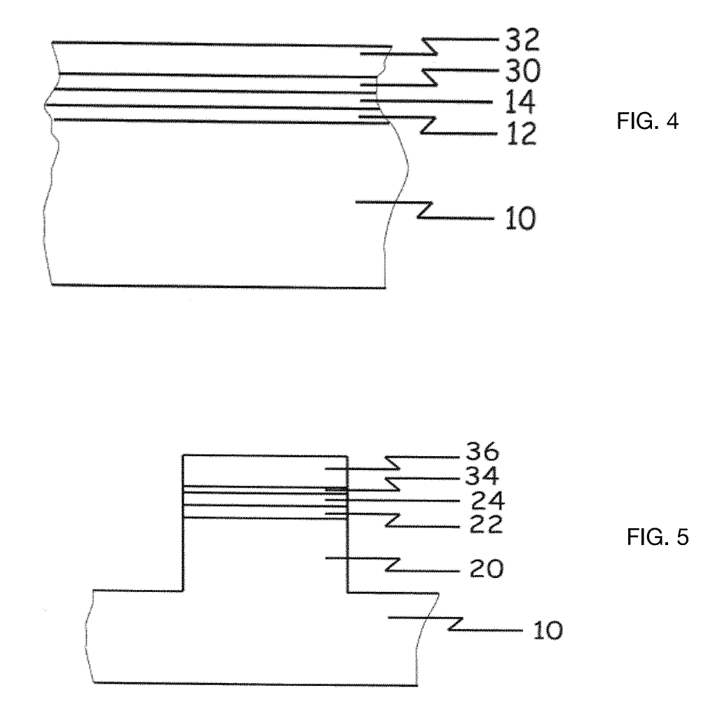

One embodiment for forming trenches into an SOI substrate having a stressed buried insulator structure beneath a thin relaxed silicon surface layer that was explained in U.S. Pat. No. 9,406,798, involves forming a pad oxide layer 30 over the silicon substrate 10, stressed buried insulator structure 12 and silicon surface layer 14 structure illustrated in FIG. 1, typically by thermal oxidation or chemical vapor deposition (CVD), followed by depositing a silicon nitride layer 32 by CVD, in the manner illustrated in FIG. 4. Both the silicon germanium or silicon nitride 32 and pad oxide 30 layers are patterned to form masking oxide 34 and nitride hard mask 36. Etching using the nitride mask 36 as a hard mask forms the structure illustrated in FIG. 5. The nitride mask 36 serves not only as a mask to a reactive ion etch (RIE) used to etch the trenches but also as a hard stop to a chemical mechanical polishing (CMP) used to planarize the silicon dioxide that fills the trenches.

Leaving the nitride hard mask 36 in place until after planarization of the trench filling material is completed may inhibit the elastic strain relief when the trenches are etched, tending to cause the compressive strain to be retained in the etched stressed buried insulator structure 22 and the surface silicon layer 24 to not be strained to a desirable extent. Accordingly, in U.S. Pat. No. 9,406,798, modifications of the trench isolation process to more efficiently allow elastic relaxation are described. Such modifications may be included in embodiments of the present invention and include using a nitride trench isolation structure liner or a more compliant pad oxide. For example, after the isolation trench etch is completed, the nitride hard mask can be removed. Preferably the hard mask is removed and elastic strain relaxation is allowed to take place uninhibited. Then a thinner nitride “liner” layer is deposited conformally over the isolation trench topography. This silicon nitride liner layer is used as the polish stop for the CMP planarization used after depositing an insulator such as silicon dioxide using, for example, high density plasma chemical vapor deposition. The nitride layer is subsequently removed from the top surface of the active area by a suitable etch process and remains on the trench sidewalls and the trench bottom.

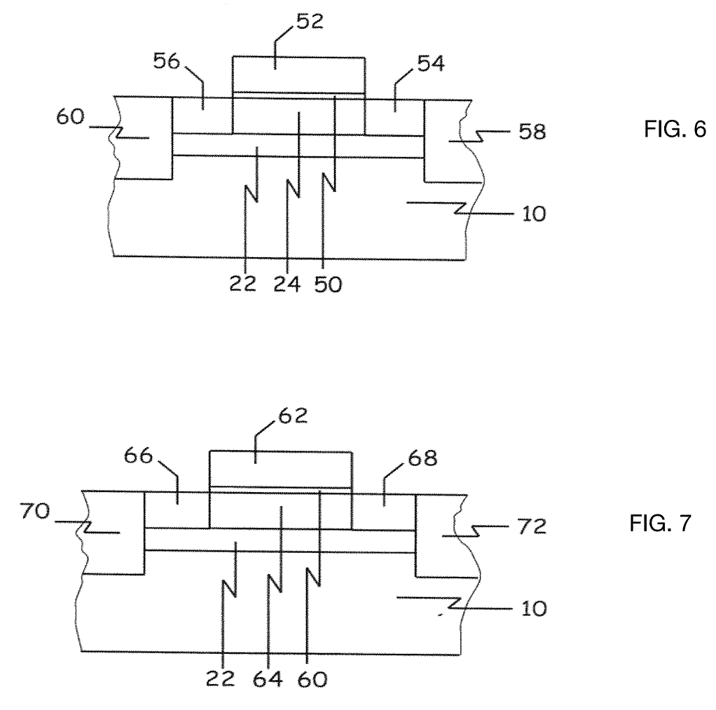

Further processing may be performed to form n-MOSFET devices and, as desired, p-channel MOSFET (p-MOSFET) devices and CMOS circuitry. An example of a portion of a CMOS device adapted from U.S. Pat. No. 9,406,798 is illustrated in FIG. 6, which represents a two-dimensional section through a MOSFET aligned along the longitudinal axis of the device. As shown, the partially relaxed and deformed stressed buried insulator structure 22 is provided over the substrate 10 and the strained silicon surface layer 24 covers the buried insulator structure 22. For the n-MOSFET portion of the CMOS device, gate dielectric 50 separates gate electrode 52 from the silicon surface layer 24. n-type source and drain regions 54 and 56 are provided on either end of the layer 24 so that the silicon surface layer 24 acts completely or at least partially as the channel region of the illustrated n-MOSFET device. In the illustrated configuration, shallow trench isolation structures 58, 60 are formed at the ends of the source and drain regions 54, 56 and longitudinal tensile strain is induced in the active silicon layer 24 by edge relaxation of the compressively stressed buried insulator structure with deformation of the buried oxide.

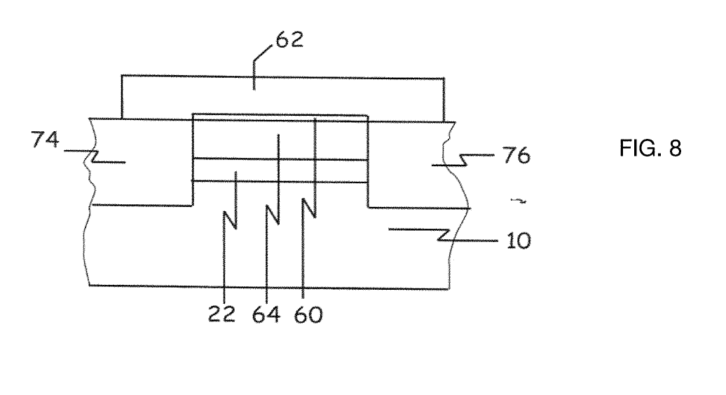

Such an n-MOSFET device may be combined with a p-MOSFET in a CMOS device. For the p-MOSFET portion of the CMOS device, illustrated in FIG. 7, a gate dielectric 60 separates a gate electrode 62 from silicon surface layer 64. p-type source and drain electrodes 66, 68 are provided on either end of the silicon surface layer 64 so that the silicon surface layer 64 acts completely or at least partially as the channel region of the p-MOSFET device. In this configuration of a CMOS device, trench isolation structures 70, 72 are preferentially formed at the ends of the source and drain regions 66, 68 far from the channel region or not formed at all so as to avoid inducing a significant longitudinal tensile strain in the channel region by edge relaxation of the stressed buried insulator structure 22. Longitudinal compressive stress may additionally be introduced into the channel of the p-MOSFET by the application of SiGe source/drain stressors. In some implementations, the SiGe source/drain stresses may be in part raised above the level of the channel for example through epitaxial growth. For the orthogonal view of the p-MOSFET portion of the CMOS device shown in FIG. 8, gate dielectric 60 separates gate electrode 62 from silicon surface layer 64 and gate electrode 62 extends over trench isolation structures 74, 76. Trench isolation structures 74, 76 may be formed with sufficiently small separation to define the width of the p-MOSFET and to induce a stress greater than 200 MPa across a major portion of surface layer 64 by edge relaxation and deformation of stressed buried insulator structure 22.

Notwithstanding the disclosure in U.S. Pat. No. 9,406,798, the inventors have found by experimentation that a new and unforeseen strain mechanism is possible when trench structures are formed in layers as described above. Strain is induced in a thin surface semiconductor layer by geometric deformation of the buried insulator layer. That is, a thin surface semiconductor layer has strain imposed by mechanical bowing of the layer due to deformation of an underlying buried insulator. More specifically the buried insulator structure is bowed in a convex fashion due to creep of the buried insulator beyond the trench sidewalls and the consequential thinning of the buried insulator in proximity to the trench sidewalls. The deformation of the buried insulator causes bending or bowing of the thin surface semiconductor layer that is well attached to the upper surface of the buried insulator. The bottom interface of the buried insulator structure remains planar (flat) and not deformed because it is constrained by the underlying structures including the buried stressor layer and the silicon wafer. The stiff and thick underlying materials do not allow any significant deformation of the buried insulator structure along its bottom interface (note that in general semiconductor wafer manufacturing, the combined thickness of the buried stressor and silicon wafer may for purposes of calculation of deformation be considered infinite compared to the size of the buried insulator structure). Only the upper boundary of the buried insulator structure is deformed because the upper boundary is only partially (minimally) constrained by the thin overlying semiconductor layer.

This latter point is of significance in determining the range of semiconductor layer thicknesses in which the bowing of the thin surface semiconductor layer will occur. The present straining mechanism is most effective when the surface semiconductor layer is thin and the degree of deformation of the buried insulator structure decreases as the thickness of the surface semiconductor layer is increased. There is a thickness of the surface semiconductor layer for which no bowing (at least no bowing of an effective degree) occurs. For large thicknesses of semiconductor overlying the buried insulator, the deformation mechanism is suppressed by the stiffness of the overlying structure in the same way as it is suppressed by the thickness and stiffness of the underlying structure. It is perhaps for these reasons that the buried insulator mechanism has not previously observed (or at least reported). The present strain mechanism therefore requires a combination of factors to be present simultaneously in the device structure: a compressively stressed layer underlying a buried insulator layer, with the buried insulator having a thickness in the range 3 to 80 nm; a thin active material layer overlying the buried insulator and having a thickness in the range 0.2 to 50 nm; and trenches etched through the thin active material layer, the buried insulator layer, the buried stressor layer and into the underlying silicon with the spacing between the trenches being less than 500 nm.

In embodiments of the present invention, the thin active material layer is a semiconductor layer and the semiconductor may be crystalline. The buried stressor layer may be an epitaxial layer of silicon germanium (SiGe) if the underlying substrate (wafer) is silicon, the SiGe having compressive stress in the plane of its interface with the underlying silicon by virtue of mismatch of crystalline lattice spacing. The SiGe is thin enough that it is not significantly relaxed by formation of defects such as dislocations. The buried stressor may be any other compatible material that has a built-in compressive stress, such as silicon nitride deposited in a state of compressive stress in the plane of the surface on which it is deposited. There are known processes for depositing such compressively stressed layers of silicon nitride.

Thus, in accordance with the present invention, a buried insulator layer (structure) is caused to deform as a result of the formation of trenches etched through an underlying compressively stressed buried stressor layer, the deformation being induced by tensile strain imposed within the buried insulator layer. This mechanism has been demonstrated specifically for the case where the buried insulator is silicon oxide (dioxide) and the buried stressor is compressively stressed epitaxial silicon germanium (SiGe) formed on the underlying silicon wafer. The interface between the silicon oxide buried insulator and the SiGe buried stressor is formed by wafer bonding. The results are shown in (exemplified by) the transmission electron micrograph in FIG. 1(a). The same micrograph is annotated in FIG. 1(b) with lines drawn to delineate the relevant interfaces.

Referring to FIG. 1(b), the relevant regions are as follows: the silicon wafer (substrate), 100; the buried stressor layer comprising epitaxial silicon germanium 102 and having a thickness of about 32 nm; the buried insulator region (e.g., buried oxide or “BOX) comprising silicon dioxide, 104 and having a thickness of about 25 nm; the thin active material layer comprising silicon 106 having a thickness of about 15 nm; the trenches 107 and 108 that have been etched through the sequence of layers 106, 104, 102 and into the substrate 100 with the spacing between the trenches being about 80 nm. The lines depicted in FIG. 1(b) describe interfaces between the various regions. The line between the silicon substrate and the silicon germanium buried stressor is essentially straight, indicating a flat and un-deformed planar interface. The line between the silicon germanium buried stressor 102 and the buried insulator 104 is essentially straight, indicating a flat and un-deformed planar interface. In contrast, the line between the buried insulator 104 and the thin active silicon layer 106 is curved, indicating a deformed (non-planar) interface between these two regions.

It is observed that some of the silicon dioxide in the region of buried insulator 104 is extending into open trench 107 to the left of the image and open trench 108 to the right. As a result, the region of buried insulator (silicon dioxide) 104 is thinner at the right and left, proximate to the trench sidewalls, than it is at its center. In this instance, with the trenches being spaced approximately 80 nm apart, the thinning of the buried insulator region 104 results in a curved upper interface with the silicon active layer 106 above.

Since in this example the trenches were formed with a separation of less than approximately 100 nm, the relaxation of the buried SiGe stressor and consequential deformation of the buried insulator region (driven by induced tensile strain in the silicon dioxide) has caused an approximately constant curvature of the buried insulator—thin semiconductor interface extending between the trenches. The curved interface has an approximately constant radius of curvature equal to 500 nm. Based on known mathematical relationships based on geometry and equilibrium mechanics, the strain in the top surface a free-standing layer of thickness 15 nm consistent with a convex bending radius of 500 nm, as seen in FIG. 1(b), may be calculated as (0.5×15)/500=1.5% tensile strain. The strain in the lower surface of the same free-standing layer is 1.5% compressive strain. In the present case, the thin active silicon layer 106 is not free standing and the strain in its upper and lower surfaces may be modified from the values +1.5% and −1.5% respectively.

In one embodiment of the invention, the magnitude of the tensile strain induced in the surface of the surface semiconductor layer is greater than may be achieved in the absence of the deformation of the buried insulator. In a general case of strain induced by elastic edge relaxation of a buried stressor, the magnitude of the tensile stress induced in the surface of the overlying semiconductor layer cannot be greater than the maximum magnitude of the compressive stress in the buried stressor layer. As such, in the present invention, the stress in the surface of the uppermost semiconductor layer is in effect amplified by the peculiar geometric shape that arises in the buried insulator region, that peculiar shape arising from structural deformation of the insulating material in the buried insulating region, and the tensile strain in the surface of the uppermost semiconductor layer may be greater in magnitude than the compressive strain in the buried stressor. This point will be discussed further below.

In the example shown in FIGS. 1(a) and 1(b), the buried SiGe stressor has an estimated in-plane compressive strain equal to 1.68% (estimated as 40% of the 4.2% lattice spacing difference between silicon and SiGe with 40% germanium alloy composition). At most, half of the strain in the SiGe buried stressor could be expected to be shared (transferred to) the overlying thin silicon layer, if the layers were adjoining. In this simplistic analysis that would lead to approximately 0.84% tensile strain in the overlying thin silicon layer and −0.84% compressive strain remaining in the SiGe buried stressor layer. In reality, much less than 50% of the strain is shared with the overlying layer because (a) the buried stressor is not completely elastically relaxed and (b) some of the strain energy is shared with the underlying silicon substrate. Furthermore, in the present case there is a significant thickness (25 nm) of silicon oxide between the top thin silicon layer and the buried stressor and much less than 50% of the strain in the SiGe buried stressor may be expected to arise in the thin silicon layer. Finite element simulations of strain for the particular structure shown in FIGS. 1(a) and 1(b) give a result of an average tensile strain of 0.27% and a maximum tensile strain of 0.77% (noting that deformation of the buried insulator region is not included in the simulations). The tensile strain indicated by the observed bending of the thin semiconductor layer is 1.5% which is considerably higher than the maximum tensile strain of 0.77% predicted by simulations in the absence of bending. As such, the deformation of the buried insulator region induced by edge relaxation of the underlying buried SiGe stressor can provide a higher amount of tensile strain in the surface of a thin semiconductor layer.

A higher amount of tensile strain is beneficial to the performance of many semiconductor devices including MOSFETs and photonic devices such as strained Ge or GeSn diode lasers or photodetectors. The tensile strain can be biaxial if the trenches surround the device. Accordingly, in some embodiments of the present invention, a device structure includes a semiconductor substrate (e.g., silicon, germanium, silicon germanium, germanium tin, etc.) with first and second walls of one or more trench isolation structures extending partially into the substrate, thus a substrate interface region extends between the first and second walls. The device structure further includes a buried stressor structure disposed on the substrate interface region and extending over a lateral extent between the first and second walls of the trench isolation structures. The buried stressor structure preferably has in-plane compressive stress. In some embodiments, the buried stressor structure may be compressively strained silicon germanium alloy grown epitaxially on a silicon substrate. In still further embodiments, the substrate may be silicon and the buried stressor structure may be compressively strained silicon nitride.

The device structure further includes a buried insulation layer disposed over the buried stressor structure. In various embodiments, the buried insulation layer comprises an oxide of a semiconductor, for example an oxide of silicon, an oxide of germanium, etc.). Where the buried insulation layer is silicon dioxide, it may have a thickness between 5 nm and 80 nm.

Disposed over the buried insulation layer is thin upper semiconductor layer, for example, silicon, silicon germanium, germanium, germanium tin, or another alloy of germanium, a group IV semiconductor, a semiconducting alloy, a compound of group IV elements, a II-VI compound semiconductor, or a III-V compound semiconductor such as GaN, InGaN, and AlGaN, etc. The thin upper semiconductor layer extends between the first and second walls of the trench isolation structures, may have a thickness between 0.2 nm and 50 nm, and has in-plane tensile strain induced within a first portion of the thin upper semiconductor layer extending between those first and second walls; the strain is induced by deformation of the buried insulation layer as described herein. In some instances, a surface of the thin semiconductor layer may have in-plane tensile strain along two perpendicular directions, or even radially in the case of a structure with circular or other cross-section when viewed from above.

Although the present invention is described for use with thin upper semiconductor layers, the presence of the deformed buried oxide layer enables strain to be induced in any overlaying thin material. Therefore, thin films other than semiconductor layers may be strained using the methods and structures of the present invention. Such strain may be used to affect the properties of such thin films in desired fashions.

The deformation of the buried insulation layer is caused by edge relaxation of the buried stressor structure. Such edge relaxation of the buried insulation layer may be non-uniform over a lateral extent of the buried insulation layer between the first and second walls of the trench isolation structure. That lateral extent between the first and second walls may be less than 500 nm.

In various embodiments, an integrated circuit device, for example, a transistor a laser, a light emitting diode, etc. has an active region at least partially in the first portion of the thin upper semiconductor layer. Accordingly, the device structure may also include a gate dielectric layer on the thin upper semiconductor layer, separating the thin upper semiconductor layer from a gate electrode such that the upper surface of the thin semiconductor layer extends between the first and second walls provides at least a part of a channel region of a MOS transistor.

Thus, described herein is a strained SOI structure including a thin active upper layer (typically a semiconductor layer); a buried stressor layer on a silicon substrate; and an insulator layer of less than 80 nm thickness disposed between the thin active semiconductor and the buried stressor and configured to induce a tensile strain in the surface of the thin active semiconductor layer, wherein the insulator layer is deformed by tensile strain induced by edge relaxation of the buried stressor layer. In various embodiments, the buried stressor layer is epitaxial silicon germanium and the buried insulator layer is silicon dioxide. In some embodiments, the thin active semiconductor layer has a thickness in the range 0.2 nm to 50 nm and the buried insulator oxide layer has a thickness in the range 5 nm to 80 nm.

In one embodiment, a process for forming the layered structure involves a “wafer bonding” step. In more detail, a silicon oxide layer of thickness in the range 5 nm to 80 nm is formed on a silicon wafer (the donor wafer) and an in-plane compressively strained SiGe layer of thickness in the range 5 nm to 70 nm is formed by an epitaxial growth process (such as chemical vapor deposition, “CVD”) on a separate wafer (the handle wafer). The SiGe layer may have an alloy composition between 5% germanium and 100% germanium and the SiGe layer may have a thickness less than a “critical thickness” at which plastic relaxation occurs with formation of extended defects such as dislocations. Embodiments of the invention are not limited to a SiGe layer thickness less than a critical thickness, however, because extended defects such as dislocations can be tolerated by virtue of the buried oxide layer, which prevents such defects extending into the active semiconductor layer above. The donor wafer is subsequently bonded to the handle wafer with the oxide layer on the donor being bonded adjacent to the SiGe layer on the handle. In other embodiments, an additional thin layer of silicon is provided on top of the SiGe layer on the handle wafer before the donor wafer is bonded to the handle wafer. The additional layer of silicon may assist in the boding process by providing a preferred boding interface. The additional layer of silicon may be epitaxial. The additional layer of silicon may have a thickness in the range 1 nm-20 nm.

A majority of the thickness of the silicon donor wafer is then removed by any combination of processes to leave a thin layer of silicon (thickness in the range 0.2 nm to 50 nm) remaining on the silicon oxide layer and the silicon oxide layer bonded above the SiGe stressor layer. In the specific example of FIGS. 1(a) and 1(b), the layer thicknesses were 15 nm thin silicon; 25 nm silicon oxide; 32 nm SiGe. The range of processes available for thinning the silicon layer include: wafer cleaving (after proton or hydrogen implantation); wafer polishing; chemical mechanical polishing (“CMP”); and cyclic oxidation and wet etching with a solution of hydrofluoric acid.

After formation of the suitable layered structure on a silicon wafer, a pattern is created in a resistive material on the surface of the layered wafer by any known lithographic method, the pattern defining the trenches to be etched. Subsequently trenches are etched to a depth sufficient to pass through the buried stressor and into the underlying silicon. The trench etching process may be a dry etch process (such as plasma etching or reactive ion etching) or a wet etch process (e.g., using buffered HF for the SiO₂ BOX and TMAH or KOH for the Si and/or SiGe) or a combination of dry and wet etching processes. The resistive material is removed after completion of the trench etching process. After trench etching a brief thermal process may be applied and then the trenches may be filled with an insulating material such as silicon dioxide. The brief thermal process may have a duration of between 1 millisecond and 60 seconds and may reach a maximum temperature of between 600° C. and 1200° C. The thermal process may be rapid thermal annealing (RTA), flash lamp annealing, laser annealing or any other rapid heating process. At the end of the process, the buried insulator is deformed, specifically as a result of it being thinner at the trench sidewalls due to migration of some of the silicon oxide laterally beyond the boundary of the trench sidewall

In another embodiment, the tensile strain in the upper surface of the thin semiconductor layer is biaxial tensile strain. Biaxial strain is effectively uniaxial strain occurring in two orthogonal directions. Uniaxial tensile strain is obtained along a first axis if trenches define a spacing (a lateral extent) along that first axis and uniaxial tensile strain is obtained along a second axis if trenches define a spacing (a lateral extent) along that second axis. The strain between trenches is biaxial if the first and second axes are orthogonal. Stated differently, the tensile strain in the upper surface of the thin semiconductor layer is biaxial if the trenches surround the device structure containing the thin semiconductor layer. In this case of biaxial strain, the device structure is in the form of a mesa where the shape of the mesa may be rectangular, square, elliptical or circular when viewed from above.

More generally, the present invention provides a method of manufacturing a device in a layered structure in which an upper thin semiconductor layer (e.g., silicon, silicon germanium, germanium, germanium tin, or another alloy of germanium, a group IV semiconductor, a semiconducting alloy, a compound of group IV elements, a II-VI compound semiconductor, or a III-V compound semiconductor such as GaN, InGaN, and AlGaN, etc.) is disposed over a buried insulator layer (e.g., a oxide of silicon, such as silicon dioxide, an oxide of germanium, etc.) and a buried compressively strained stressor layer (e.g., silicon nitride, silicon germanium, etc.) under the buried insulator layer, where the compressively strained stressor layer disposed on an underlying semiconductor substrate. In various embodiments, such a process includes etching through the upper thin semiconductor layer, the buried insulator layer, the buried compressively strained stressor layer, and into the underlying substrate in a pattern defined by a mask layer. The etching relaxes, at least partially, the buried compressively strained stressor layer, thus causing deformation of the buried insulator layer. The deformation of the buried insulator layer induces tensile strain in an upper surface of the thin semiconductor layer across at least a first portion of a lateral extent of the thin semiconductor layer between walls of one or more trenches formed by the etching. Subsequently, an active region of a device (e.g., a transistor, such as an n-channel MOSFET, a light emitting diode, a laser, etc.) may be formed in the first portion of the surface semiconductor layer.

The tensile strain induced in the upper surface of the thin semiconductor layer may be uniaxial tensile strain or biaxial tensile strain. In each instance, inducing tensile strain in the buried insulator layer produces the deformation of the buried insulator layer. As discussed above, the buried stressor layer may be an in-plane compressively stressed silicon nitride layer and may have a compressive stress of greater than 200 MPa, prior to the etching through the buried insulator layer. Alternatively, the buried compressively strained stressor layer may be in-plane compressively strained silicon germanium.

In some embodiments, the lateral extent of the thin semiconductor layer may be 250 nm or less (e.g., 130 nm) and the tensile strain within the top surface of thin semiconductor layer may be non-uniform over that lateral extent of the thin semiconductor layer.

As explained above, the invention is not limited to use of a SiGe compressive buried stressor or a silicon upper layer. The buried compressive stressor layer may be a deposited silicon nitride layer with built-in compressive stress as formed. The upper layer may be a semiconductor other than silicon such as: germanium; a SiGe alloy; GeSn; SiC or some other group IV semiconductor; a III-V compound semiconductor, or a II-VI compound semiconductor; graphene or a transition metal dichalcogenide semiconductor.

Thus, semiconductor devices that include a strained semiconductor layer in which the strain results, at least in part, from deformation of a buried insulator layer due to edge relaxation of a buried stressor layer have been described.

What is claimed is:

1. A device structure comprising:
a semiconductor substrate having first and second walls of one or more trench isolation structures extending partially into the substrate, a substrate interface region extending between the first and second walls;
a buried stressor structure on the substrate interface region and extending over a lateral extent between the first and second walls, the buried stressor structure having in-plane compressive stress;
a buried insulation layer comprising silicon dioxide over the buried stressor structure;
a thin upper semiconductor layer over the buried insulation layer, the thin upper semiconductor layer extending between the first and second walls and having in-plane tensile strain induced within a first portion of the thin upper semiconductor layer extending between the first and second walls, the strain induced by deformation of the buried insulation layer; and
an integrated circuit device having an active region at least partially in the first portion of the thin upper semiconductor layer,
wherein the deformation of the buried insulation layer is caused by edge relaxation of the buried stressor structure.

2. The device structure of claim 1, wherein the buried insulation layer comprises silicon dioxide with a thickness between 5 nm and 80 nm.

3. The device structure of claim 1, wherein the buried stressor structure comprises compressively strained silicon germanium alloy grown epitaxially on the substrate.

4. The device structure of claim 1, wherein the buried stressor structure comprises compressively strained silicon nitride.

5. The device structure of claim 1, wherein the thin upper semiconductor layer comprises silicon.

6. The device structure of claim 1, wherein the thin upper semiconductor layer comprises at least one of: silicon germanium, germanium, germanium tin, or another alloy of germanium, a group IV semiconductor, a semiconducting alloy, a compound of group IV elements, a II-VI compound semiconductor , and a III-V compound semiconductor.

7. The device structure of claim 1, wherein the thin upper semiconductor layer has a thickness between 0.2 nm and 50 nm.

8. The device structure of claim 1, further comprising a gate dielectric layer on the thin upper semiconductor layer separating the thin upper semiconductor layer from a gate electrode such that the upper surface of the thin semiconductor layer extending between the first and second walls provides at least a part of a channel region of a MOS transistor.

9. The device structure of claim 8, wherein partial relaxation within the buried insulation layer is non-uniform over a lateral extent between the first and second walls.

10. The device structure of claim 9, wherein the lateral extent between the first and second walls is less than 500 nm.

11. The device structure of claim 1, wherein the thin semiconductor layer is silicon and a surface of the thin semiconductor layer has in-plane tensile strain along two perpendicular directions.

12. A method of manufacturing a device in a layered structure in which an upper thin semiconductor layer is disposed over a buried insulator layer and a buried compressively strained stressor layer under the buried insulator layer, the compressively strained stressor layer disposed on an underlying semiconductor substrate, the method comprising:
etching through the upper thin semiconductor layer, the buried insulator layer, the buried compressively strained stressor layer, and into the underlying substrate in a pattern defined by a mask layer, thereby at least partially relaxing the buried compressively strained stressor layer and causing deformation of the buried insulator layer, the deformation of the buried insulator layer inducing tensile strain in an upper surface of the thin semiconductor layer across at least a first portion of a lateral extent of the thin semiconductor layer between walls of one or more trenches formed by the etching; and
forming an active region of the device in the first portion of the surface semiconductor layer.

13. The method of claim 12, wherein the tensile strain induced in the upper surface of the thin semiconductor layer is uniaxial tensile strain.

14. The method of claim 12, wherein the tensile strain induced in the upper surface of the thin semiconductor layer is biaxial tensile strain.

15. The method of claim 12, wherein inducing tensile strain in the buried insulator layer produces the deformation of the buried insulator layer.

16. The method of claim 12, wherein the buried insulator layer comprises silicon dioxide

17. The method of claim 12, wherein the thin semiconductor layer is one of: silicon, silicon germanium, germanium, germanium tin, or another alloy of germanium, a group IV semiconductor, a semiconducting alloy, a compound of group IV elements, a II-VI compound semiconductor, and a III-V compound semiconductor.

18. The method of claim 12, wherein the buried stressor layer comprises an in-plane compressively stressed silicon germanium layer and the substrate consists essentially of silicon.

19. The method of claim 12, wherein the buried insulator layer is coupled to the buried stressor layer through a wafer bonding process.

20. The method of claim 12, wherein the tensile strain within the top surface of thin semiconductor layer is non-uniform over the lateral extent of the thin semiconductor layer.
